(19) United States
(12) Patent Application Publication
(10) Pub. No.: US 2011/0146575 A1
(43) Pub. Date: Jun. 23, 2011

(54) EVAPORATION SOURCE AND DEPOSITION APPARATUS HAVING THE SAME

(75) Inventors: Seung-Ho Choi, Yongin-city (KR); Suk-Won Jung, Yongin-city (KR); Seung-Ho Myoung, Yongin-city (KR); Cheol-Lae Roh, Yongin-city (KR)

(73) Assignee: Samsung Mobile Display Co., Ltd., Yongin-city (KR)

(21) Appl. No.: 12/972,369

(22) Filed: Dec. 17, 2010

(30) Foreign Application Priority Data
Dec. 22, 2009 (KR) 10-2009-0128890

(51) Int. Cl. C23C 16/04; C23C 16/448; C23C 16/00; C23C 16/44

(52) U.S. Cl. 118/721; 118/726

(57) ABSTRACT

An evaporation source is disclosed. In one embodiment, the evaporation source includes: i) a crucible being open on one side thereof and configured to store a deposition material and ii) a nozzle section located on the open side of the crucible and comprising a plurality of nozzles, wherein each of the nozzles has a sidewall configured to spray the deposition material therethrough, wherein the side wall has an inclined portion. The evaporation source also includes i) a heater configured to heat the crucible and ii) a housing configured to accommodate the crucible, the nozzle section, and the heater, wherein the nozzle section has a maximum spray angle less than about 60°.

### RELATED APPLICATIONS

This application claims the benefit of Korean Patent Application No. 2009-128890, filed Dec. 22, 2009, the disclosure of which is hereby incorporated herein by reference in its entirety.

This application relates to U.S. patent application entitled “Linear to evaporation source and deposition apparatus having the same” (Attorney docket: SMDYOU.129AUS), which is concurrently filed as this application and incorporated herein by reference in its entirety.

### BACKGROUND

1. Field

The described technology generally relates to an evaporation source and a deposition apparatus having the same for flat panel displays.

2. Description of the Related Technology

Flat panel displays have replaced cathode ray tube displays due to their light weight and thin profile. Typical examples of such displays include liquid crystal displays (LCDs) and organic light emitting diode displays (OLEDs). OLEDs generally have better luminance and viewing angle characteristics, and require no backlight, so that they can be realized as ultra thin displays.

These OLEDs display images using a phenomenon that electrons and holes injected into an organic thin film through a cathode and an anode are recombined to form excitons, and thus light having a specific wavelength is emitted by the release of energy resulting from de-excitation of the excitons.

OLED displays are generally manufactured by a photolithography method or a deposition method to selectively form a cathode, an anode, and an organic thin film on a substrate formed of, for example, glass, stainless steel, or synthetic resin. In the deposition method, a deposition material is evaporated or sublimated, deposited under vacuum, and selectively etched. Alternatively, a deposition material is selectively deposited using a mask assembly having a plurality of slits in a predetermined pattern.

The photolithography method generally calls for applying photoresist to a predetermined region, and then performing wet- or dry-etching on the applied photoresist. In the process of removing or etching the photoresist, moisture may penetrate. For materials which degrade in the presence of moisture, such as an organic thin film, deposition is the primary method used to form a thin film.

### SUMMARY

One inventive aspect is an evaporation source in which a deposition nozzle has a structure to minimize a shadow effect, and a deposition apparatus having the same for flat panel displays, realizing substantially uniform deposition of layers of the flat panel displays.

Another aspect is an evaporation source which includes a crucible being open on one side thereof and storing a deposition material, a nozzle section located on the open side of the crucible and having a plurality of nozzles, each of which is inclined on a predetermined region of an inner wall thereof, a heater heating the crucible, and a housing accommodating the crucible, the nozzle section, and the heater. The nozzle section has a maximum spray angle less than 60°.

Another aspect is a deposition apparatus which includes a process chamber, an evaporation source located on one side of the process chamber and including at least one nozzle that is inclined on a predetermined region of an inner wall thereof, a substrate holder disposed opposite the evaporation source, and a mask assembly interposed between the substrate holder and the evaporation source and having a plurality of slits, each of which has sidewalls inclined to a surface of the mask assembly at a first inclined angle. The evaporation source has a maximum spray angle less than the first inclined angle.

Another aspect is an evaporation source for manufacturing flat panel displays, comprising: a crucible being open on one side thereof and configured to store a deposition material; a nozzle section located on the open side of the crucible and comprising a plurality of nozzles, wherein each of the nozzles has a sidewall configured to spray the deposition material therethrough, wherein the side wall has an inclined portion; a heater configured to heat the crucible; and a housing configured to accommodate the crucible, the nozzle section, and the heater, wherein the nozzle section has a maximum spray angle less than about 60°.

In the above source, the crucible extends in one direction and includes at least one partition dividing an internal space of the crucible. In the above source, the at least one partition includes a groove formed in an upper portion thereof.

In the above source, the side wall has a non-inclined portion which is closer to the crucible than the inclined portion, wherein the inclined portion has a height (h), which satisfies the following expression:

$$h = \frac{tan ( 90 - \frac{θ}{2} ) tan θ}{tan ( 90 - \frac{θ}{2} ) - tan θ} R$$

where θ is the maximum spray angle of the nozzle section, and R is the inner diameter of the non-inclined portion of the side wall.

In the above source, the side wall has a non-inclined portion which is closer to the crucible than the inclined portion, wherein the inclined portion has a top and a bottom which is closer to the crucible than the top, wherein the inclined portion is substantially gradually inclined such that the inner diameter of the top is greater than that of the bottom, wherein the thickness (t) of the bottom of the inclined portion satisfies the following expression:

$$t = \frac{tan θ}{tan ( 90 - \frac{θ}{2} ) - tan θ} R$$

where θ is the maximum spray angle of the nozzle section, and R is the inner diameter of the non-inclined portion of the side wall, and wherein the thickness (t) is substantially the same as the thickness of the non-inclined portion of the side wall.

In the above source, the side wall has a non-inclined portion which is closer to the crucible than the inclined portion, wherein the inclined portion has a height (h) and thickness (t), which satisfy the following expression:

$$\frac{h}{t} = tan ( 90 - \frac{θ}{2} )$$

where θ is the maximum spray angle of the nozzle section, wherein the inclined portion has a top and a bottom which is closer to the crucible than the top, wherein the inclined portion is substantially gradually inclined such that the to inner diameter of the top is greater than that of the bottom, and wherein t is the thickness of the bottom of the inclined portion which is substantially the same as the thickness of the non-inclined portion of the side wall.

In the above source, the deposition material stored in the crucible includes an organic material. In the above source, the housing is further is configured to accommodate a plurality of crucibles and a nozzle section located on an open side of the crucibles. In the above source, the side wall has a non-inclined portion which is closer to the crucible than the inclined portion, and wherein the height of the non-inclined portion is greater than that of the inclined portion.

Another aspect is a deposition apparatus for manufacturing flat panel displays, comprising: an evaporation source configured to contain and spray a deposition material; a mask assembly having a plurality of slits and configured to deposit the deposition material onto a substrate through the slits, wherein each of the slits has sidewalls inclined to a surface of the mask assembly at a first inclined angle; a substrate holder configured to hold the substrate and located opposite the evaporation source with respect to the mask assembly; and a process chamber configured to accommodate the evaporation source, substrate holder and mask assembly, wherein the evaporation source has a maximum spray angle less than the first inclined angle.

In the above apparatus, the maximum spray angle of the evaporation source is less than about 60°. In the above source, the evaporation source further comprises: a crucible being open on one side thereof and configured to store the deposition material; a nozzle section located on the open side of the crucible and having a plurality of nozzles, wherein each of the nozzles has a sidewall configured to spray the deposition material therethrough, and wherein the side wall has i) an inclined portion and ii) a non-inclined portion which is closer to the crucible than the inclined portion; a heater configured to heat the crucible; and a housing configured to accommodate the crucible, the is nozzle section, and the heater.

In the above apparatus, the inclined portion has a height (h), which satisfies the following expression:

$$h = \frac{tan ( 90 - \frac{θ}{2} ) tan θ}{tan ( 90 - \frac{θ}{2} ) - tan θ} R$$

where θ is the maximum spray angle of the nozzle section, and R is the inner diameter of the non-inclined portion of the side wall.

In the above apparatus, the inclined portion has a top and a bottom which is closer to the crucible than the top, wherein the inclined portion is substantially gradually inclined such that the inner diameter of the top is greater than that of the bottom, wherein the thickness (t) of the bottom of the inclined portion satisfies the following expression:

$$t = \frac{tan θ}{tan ( 90 - \frac{θ}{2} ) - tan θ} R$$

where θ is the maximum spray angle of the nozzle section, and R is the inner diameter of the non-inclined portion of the side wall, and wherein the thickness (t) is substantially the same as the thickness of the non-inclined portion of the side wall.

In the above apparatus, the inclined portion has a height (h) and thickness (t), which satisfy the following expression:

$$\frac{h}{t} = tan ( 90 - \frac{θ}{2} )$$

where θ is the maximum spray angle of the nozzle section, wherein the inclined portion has a top and a bottom which is closer to the crucible than the top, wherein the inclined portion is substantially gradually inclined such that the inner diameter of the top is greater than that of the bottom, and wherein t is the thickness of the bottom of the inclined portion which is substantially the same as the thickness of the non-inclined portion of the side wall. The above apparatus further comprises a transfer unit configured to reciprocate the evaporation source in a predetermined direction.

Another aspect is an evaporation source for manufacturing flat panel displays, comprising: a container configured to store a deposition material; a nozzle being in fluid communication with the container, wherein the nozzle has a sidewall configured to spray the deposition material onto a substrate to be deposited, wherein the side wall has an inclined portion, wherein the inclined portion has a top and a bottom which is closer to the container than the top, and wherein the top of the inclined portion forms an inclined angle with respect to the bottom such that the innerdiameter of the top is greater than that of the bottom, and wherein the inclined angle is greater than about 60° and less than 90°; and a housing configured to accommodate the container and the nozzle.

In the above source, the nozzle has a maximum spray angle less than about 60°. In the above source, the side wall includes a non-inclined portion which is closer to the container than the inclined portion, wherein the thickness (t) of the bottom of the inclined portion satisfies the following expression:

$$t = \frac{tan θ}{tan ( 90 - \frac{θ}{2} ) - tan θ} R$$

where θ is the maximum spray angle of the nozzle section, and R is the inner diameter of the non-inclined portion of the side wall, and wherein the thickness (t) is substantially the same as the thickness of the non-inclined portion of the side wall of the nozzle.

In the above source, the side wall includes a non-inclined portion which is closer to the container than the inclined portion, wherein the inclined portion has a height (h) and thickness (t), which satisfy the following expression:

$$\frac{h}{t} = tan ( 90 - \frac{θ}{2} )$$

where θ is the maximum spray angle of the nozzle section, and wherein t is the thickness of the bottom of the inclined portion which is substantially the same as the thickness of the non-inclined portion of the side wall.

### BRIEF DESCRIPTION OF THE DRAWINGS

FIG. 1 is a schematic view illustrating a deposition apparatus according to an embodiment.

FIG. 2A is a perspective view illustrating an evaporation source for a deposition apparatus according to an embodiment.

FIG. 2B is a cross-sectional view illustrating an evaporation source for a deposition apparatus according to an embodiment.

FIG. 3 is an enlarged view of region A of FIG. 2B.

FIG. 4 is a graph showing a relation between thickness and height of the predetermined region of a nozzle and an opening width of the is nozzle with respect to the maximum spray angle of the evaporation source.

### DETAILED DESCRIPTION

A deposition machine typically includes an evaporation source. The evaporation source generally includes i) a crucible being open on one side for storing a deposition material, ii) a heater to heat the crucible, iii) a nozzle section located on the open side of the crucible, and iv) a housing accommodating the crucible, the heater, and the nozzle section. To improve deposition efficiency, a linear evaporation source may be used as the evaporation source. In this design, the crucible extends in one linear direction, or a plurality of crucibles and a nozzle section are installed in the housing along a line.

A deposition machine using the above-mentioned mask assembly is designed to reduce a “shadow effect” phenomenon that a deposition material is non-uniformly deposited on a substrate. This is accomplished by forming sidewalls of the slits in the mask assembly in a predetermined pattern so as to have a first inclined angle with respect to the surface of the mask assembly. However, since the deposition material evaporated from the source is scattered in various spray angles, eliminating the shadow effect is problematic.

Reference will now be made in detail to the disclosed embodiments, examples of which are shown in the accompanying drawings, wherein like reference numerals refer to the like elements throughout. In the drawings, the lengths and thicknesses of layers and regions may be exaggerated for clarity.

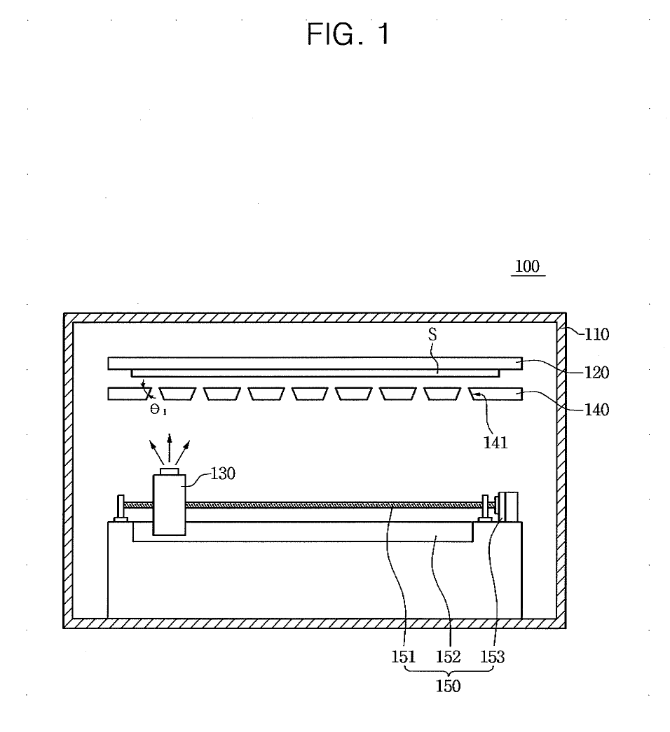

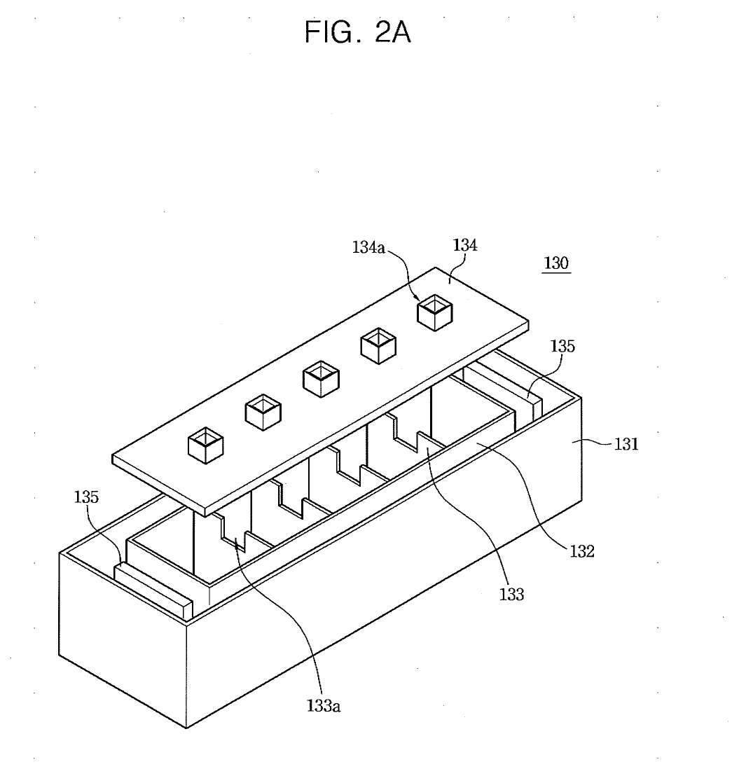

FIG. 1 is a schematic view illustrating a deposition apparatus according to an embodiment. FIG. 2A is a perspective view illustrating an evaporation source for a deposition apparatus according to an embodiment. FIG. 2B is a cross-sectional view illustrating an evaporation source for a deposition apparatus according to an embodiment.

Referring to FIGS. 1, 2A and 2B, the deposition apparatus 100 includes i) a process chamber 110, ii) an evaporation source 130 located on one side of the process chamber 110 and including at least one nozzle that is inclined, on the predetermined region of an inner wall thereof, toward an outer wall of the nozzle, and iii) a substrate holder 120 disposed opposite the evaporation source 130. The apparatus 100 further includes a mask assembly 140 interposed between the substrate holder 120 and the evaporation source 130 and having a plurality of slits 141, each of which has sidewalls inclined to a surface of the mask assembly 140 at a first inclined angle θ₁. In one embodiment, the evaporation source 130 has a maximum spray angle less than the first inclined angle θ₁.

The process chamber 110 is configured to provide a space for a deposition process. The process chamber 110 may include a loading/unloading gate (not shown) through which a substrate S is loaded or unloaded, and an exhaust port (not shown) connected with a vacuum pump (not shown) to control an internal pressure of the process chamber 110 and exhaust a deposition material that is not deposited on the substrate S.

The substrate holder 120 is configured to hold the substrate S loaded into the process chamber 110, and may include a separate clamping member (not shown) for clamping the substrate S while the deposition process is performed.

In one embodiment, the evaporation source 130 is located on a lower side of the process chamber 110, that the substrate holder 120 is located on an upper side of the process chamber 110, and that the substrate S is clamped to the substrate holder 120 so as to be substantially parallel to the horizontal plane. Alternatively, the substrate holder 120 and the evaporation source 130 may be located on different sides such that the substrate S clamped to the substrate holder 120 has an angle of about 70° to about 110° with respect to the horizontal plane. Thereby, it is possible to prevent the substrate from sagging due to gravity.

Referring to FIG. 2A, the evaporation source 130 includes a crucible or a deposition material container 132 having an open upper portion and storing a deposition material and a nozzle section 134 located on the open upper portion of the crucible 132 and having a plurality of nozzles, each of which is inclined on the predetermined region of an inner wall thereof. The evaporation source 130 further includes heaters 135 located on opposite sides of the crucible 132 and heating the crucible 132, and a housing 131 accommodating the crucible 132, the nozzle section 134, and the heaters 135.

In one embodiment, the evaporation source 130 is located on the lower side of the process chamber 110, and thus the upper portion of the crucible 132 is open. Alternatively, the crucible 132 may be open to a lateral or lower portion depending on the position of the evaporation source 130.

The crucible 132 is configured to store a deposition material such as an organic material. As illustrated in FIGS. 2A and 2B, the crucible 132 is constructed to extend in one direction, and may include a plurality of partitions 133 for dividing an internal space thereof such that the deposition material is not stored leaning in one direction.

Here, each partition 133 is provided with a stepped recess or a groove 133a in an upper portion thereof, so that the deposition material evaporated by the heaters 135 can freely migrate through the upper portion of the crucible 132. Thereby, the evaporated deposition material can be substantially uniformly sprayed through each nozzle 134a of the nozzle section 134 due to a pressure difference thereof.

In one embodiment, the evaporation source 130 is a linear evaporation source having the crucible 132 constructed to extend in one direction. Alternatively, the evaporation source 130 may include a linear evaporation source in which a plurality of crucibles are accommodated in the housing 131 in one direction, or a single point evaporation source.

Further, when the evaporation source 130 is the linear evaporation source having a predetermined length in one direction, the deposition apparatus 100 may further include a transfer unit 150 (see FIG. 1), which reciprocates the evaporation source 130 in substantially horizontal and substantially vertical directions to allow the deposition material to be easily sprayed on a front surface of the substrate S. The transfer unit 150 includes a ball screw 151, a motor 153 rotating the ball screw 151, and a guide 152 controlling a moving direction of the evaporation source 130.

The nozzle section 134 is configured to spray the deposition material evaporated by the heaters 135 to the substrate S through the nozzles 134a. The inner wall of each nozzle 134a is inclined on a predetermined region thereof toward an outer wall of the nozzle 134a. In one embodiment, a height and thickness of the inclined predetermined region of the inner wall are controlled such that a maximum spray angle (θ₂: will be discussed later) of the evaporation source is set to be less than the first inclined angle θ₁ of the mask assembly. Since the deposition material is substantially uniformly formed on layers of flat panel displays, a shadow effect (causing non-uniform deposition layers) is minimized or substantially prevented.

The heaters 135 are configured to heat the crucible 132 to evaporate the deposition material stored in the crucible 132. The heaters 135 may be located on a side of the crucible 132 opposite to the open side of the crucible 132. In this embodiment, it may take more time until the deposition material is heated and evaporated by the heaters 135. As such, to transmit most heat to the deposition material located adjacent to the open side of the crucible 132 such that the deposition material can be easily evaporated, the heaters 135 may be located on sides of the crucible 132. As one example, the heaters 135 may be located on opposite sides of the crucible 132 when the to upper side of the crucible 132 is open as shown in FIGS. 2A and 2B. As another example, the heaters 135 may be located so as to surround the sides of the crucible 132. In another embodiment, the heaters 135 are located only on short sides of the housing 131. In still another embodiment, the heaters 135 are located only on long sides of the housing 131.

The mask assembly 140 is interposed between the substrate holder 120 and the linear evaporation source 130, and is configured to deposit the deposition material sprayed from the linear evaporation source 130 on the substrate S in a predetermined pattern. The mask assembly 140 includes a plurality of slits 141 formed in a predetermined pattern, in which the sidewalls of each slit 141 are inclined to the surface of the mask assembly at the first inclined angle θ₁ (see FIG. 1).

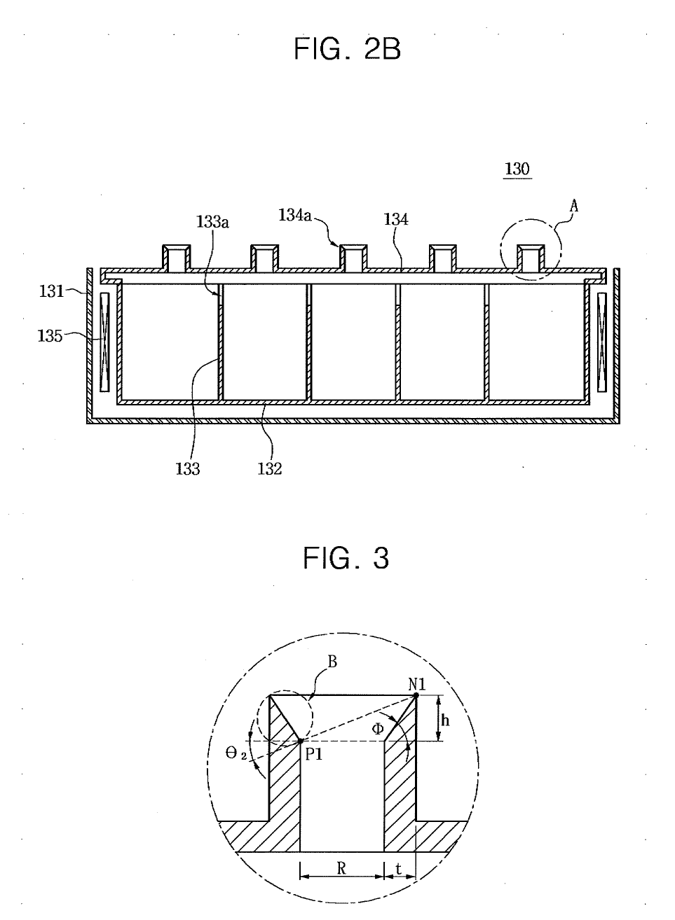

FIG. 3 is an enlarged view of region A of FIG. 2B in which the nozzle of an evaporation source is enlarged in a deposition apparatus according to an embodiment.

A method of controlling a maximum spray angle of the evaporation source 130 will be described with reference to FIG. 3. When a predetermined region B (or upper inclined portion) of each nozzle 134a is inclined, the deposition material is sprayed from the nozzle 134a. The side wall of each nozzle 134a has also a lower non-inclined portion. The deposition material may be sprayed in one of the following three manners. In a first manner, the deposition material is sprayed without colliding with the predetermined region B of the nozzle 134a. In a second manner, the deposition material is sprayed after colliding with the predetermined region B of one inner wall of the nozzle 134a. In a third manner, the deposition material is sprayed after primarily colliding with the predetermined region B of one inner wall of the nozzle 134a and then secondarily colliding with the predetermined region B of the other opposite inner wall of the nozzle 134a.

Here, considering that the predetermined region B of the nozzle 134a is inclined, the deposition material sprayed from the nozzle 134a using the second manner has the maximum spray angle. In the second manner, when sprayed, the deposition material collides at a point where one inner wall of the nozzle 134a begins to be inclined, i.e., an inclination starting point P1, and then passes directly above an upper end of the other opposite inner wall of the nozzle 134a. The maximum spray angle of the evaporation source 130 becomes an angle θ₂ between a line connecting the inclination starting point P1 of one inner wall of the nozzle 134a with the upper end N1 of the other opposite inner wall of the nozzle 134a and a horizontal line passing through the inclination starting point P1.

Thus, if the predetermined region B has a height h, a thickness t, and if the nozzle 134a has a width R, the maximum spray angle θ₂ of the evaporation source 130 satisfies expression (1) below.

$$tan {θ}_{2} = \frac{h}{( t + R )} \qquad ( 1 )$$

Further, if the predetermined region B has an inclined angle Φ, the inclined angle Φ of the predetermined region B satisfies expression (2) below.

$$tan Φ = \frac{h}{t} \qquad ( 2 )$$

According to expressions (1) and (2), correlations between the height h and thickness t of the predetermined region B and the width R of the nozzle 134a for the maximum spray angle θ₂ of the evaporation source 130 satisfy expressions (3) and (4) below.

$$\begin{matrix}t = \frac{tan {θ}_{2}}{tan Φ - tan {θ}_{2}} R & ( 3 ) \\ h = \frac{tan Φ \cdot tan {θ}_{2}}{tan Φ - tan {θ}_{2}} R & ( 4 )\end{matrix}$$

Here, the deposition material colliding at the inclination starting point P1 of the predetermined region B must meet the condition that an incident angle relative to the normal of an inclined face of the predetermined region B must be least in order to have the maximum spray angle on the basis of the Huygens-Fermat principle. Thus, since the maximum spray angle θ₂ of the evaporation source 130 is a spray angle, i.e., a sum of incident and reflective angles, of the deposition material moving along the horizontal line passing through the inclination starting point P1 to collide at the inclination starting point P1, each of the incident and reflective angles of the deposition material sprayed at the maximum spray angle θ₂ of the evaporation source 130 becomes the half of the maximum spray angle

$${θ}_{2} , i . e . , \frac{{θ}_{2}}{2} .$$

Accordingly, the maximum spray angle θ₂ of the evaporation source 130 and the inclined angle Φ of the predetermined region B satisfy expression (5) below. When the following expression (5) is applied to the preceding expressions (3) and (4), the following expressions (6) and (7) can be obtained.

$$\begin{matrix}tan Φ = tan ( 90 - \frac{{θ}_{2}}{2} ) & ( 5 ) \\ t = \frac{tan {θ}_{2}}{tan ( 90 - \frac{{θ}_{2}}{2} ) - tan {θ}_{2}} R & ( 6 ) \\ h = \frac{tan ( 90 - \frac{{θ}_{2}}{2} ) tan {θ}_{2}}{tan ( 90 - \frac{{θ}_{2}}{2} ) - tan {θ}_{2}} R & ( 7 )\end{matrix}$$

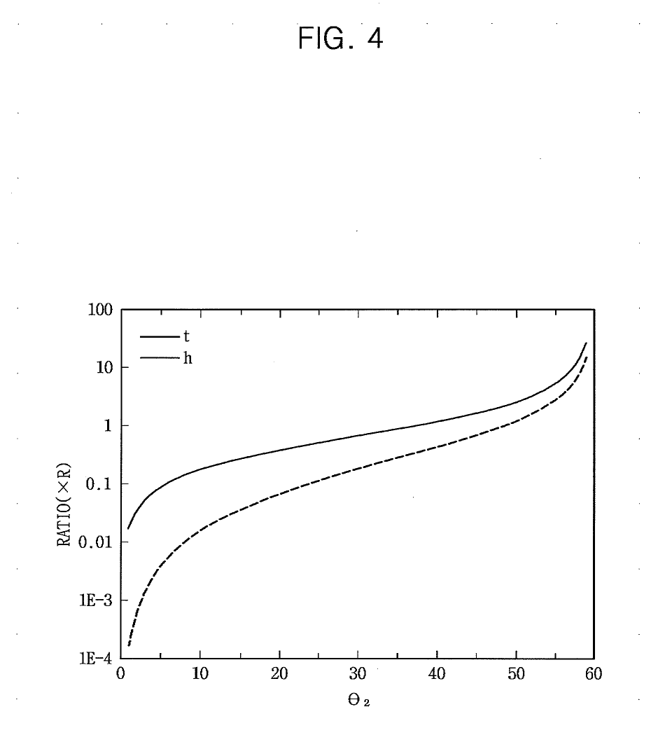

FIG. 4 is a graph showing a ratio of the thickness t and height h of the predetermined region B of the nozzle 134a to the opening width R of the is nozzle 134a with respect to the maximum spray angle θ₂ of the evaporation source 130 according to expressions (6) and (7).

In one embodiment, the maximum spray angle θ₂ of the evaporation source 130 is set to be less than the first inclined angle θ₁, of the sidewall of the slit 141 of the mask assembly 140. In this embodiment, the ratio of the thickness t and height h of the predetermined region B of the nozzle 134a to the opening width R of the nozzle 134a is determined with respect to the maximum spray angle θ₂ of the evaporation source 130 which is set with reference to FIG. 4. Thereby, the deposition apparatus 100 minimizes or substantially prevents the shadow effect.

Here, since the thickness t and height h of the predetermined region B of the nozzle 134a are real values, and thus cannot have negative or infinite values, the maximum spray angle θ₂ of the evaporation source 130 must satisfy the following expression (8).

$$tan ( 90 - \frac{{θ}_{2}}{2} ) - tan {θ}_{2} \geq 0 \qquad ( 8 )$$

Using the well-known values of the trigonometric functions, the maximum spray angle θ₂ of the evaporation source 130, which satisfies expression (8), is less than about 60°. In this embodiment, the inclined angle Φ of the predetermined region B is greater than about 60° and less than 90° (see expression (5)). The range of the maximum spray angle θ₂ is from about 30° to about 90°.

According to at least one of the disclosed embodiments, the deposition material sprayed from the evaporation source is selectively deposited on the substrate using the mask assembly that has the plurality of slits, each of which has the sidewall thereof inclined to the surface of the mask assembly at a first inclined angle, and is formed in a predetermined pattern. Further, the maximum spray angle of the evaporation source is set to be less than the first inclined angle of the sidewall of each slit of the mask assembly, and the maximum spray angle of the evaporation source is set to be less than about 60°, thereby minimizing or substantially preventing the shadow effect.

The disclosed embodiments are not considered to be limiting and may cover various modifications and equivalent arrangements included within the spirit and scope of the appended claims.

What is claimed is:

1. An evaporation source for manufacturing flat panel displays, comprising:
a crucible being open on one side thereof and configured to store a deposition material;
a nozzle section located on the open side of the crucible and comprising a plurality of nozzles, wherein each of the nozzles has a sidewall configured to spray the deposition material therethrough, wherein the side wall has an inclined portion; a heater configured to heat the crucible; and
a housing configured to accommodate the crucible, the nozzle section, and the heater,
wherein the nozzle section has a maximum spray angle less than about 60°.

2. The evaporation source according to claim 1, wherein the crucible extends in one direction and includes at least one partition dividing an internal space of the crucible.

3. The evaporation source according to claim 2, wherein the at least one partition includes a groove formed in an upper portion thereof.

4. The evaporation source according to claim 1, wherein the side wall has a non-inclined portion which is closer to the crucible than the inclined portion, wherein the inclined portion has a height (h), which satisfies the following expression:
$$h = \frac{tan ( 90 - \frac{θ}{2} ) tan θ}{tan ( 90 - \frac{θ}{2} ) - tan θ} R$$
where θ is the maximum spray angle of the nozzle section, and R is the inner diameter of the non-inclined portion of the side wall.

5. The evaporation source according to claim 1, wherein the side wall has a non-inclined portion which is closer to the crucible than the inclined portion, wherein the inclined portion has a top and a bottom which is closer to to the crucible than the top, wherein the inclined portion is substantially gradually inclined such that the inner diameter of the top is greater than that of the bottom, wherein the thickness (t) of the bottom of the inclined portion satisfies the following expression:
$$t = \frac{tan θ}{tan ( 90 - \frac{θ}{2} ) - tan θ} R$$
where θ is the maximum spray angle of the nozzle section, and R is the inner diameter of the non-inclined portion of the side wall, and wherein the thickness (t) is substantially the same as the thickness of the non-inclined portion of the side wall.

6. The evaporation source according to claim 1, wherein the side wall has a non-inclined portion which is closer to the crucible than the inclined portion, wherein the inclined portion has a height (h) and thickness (t), which satisfy the following expression:
$$\frac{h}{t} = tan ( 90 - \frac{θ}{2} )$$
where θ is the maximum spray angle of the nozzle section, wherein the inclined portion has a top and a bottom which is closer to the crucible than the top, wherein the inclined portion is substantially gradually inclined such that the inner diameter of the top is greater than that of the bottom, and wherein t is the thickness of the bottom of the inclined portion which is substantially the same as the thickness of the non-inclined portion of the side wall.

7. The evaporation source according to claim 1, wherein the deposition material stored in the crucible includes an organic material.

8. The evaporation source according to claim 1, wherein the housing is further configured to accommodate a plurality of crucibles and a nozzle section located on an open side of the crucibles.

9. The evaporation source according to claim 1, wherein the side wall has a non-inclined portion which is closer to the crucible than the inclined portion, and wherein the height of the non-inclined portion is greater than that of the inclined portion.

10. A deposition apparatus for manufacturing flat panel displays, comprising:
an evaporation source configured to contain and spray a deposition material; a mask assembly having a plurality of slits and configured to deposit the deposition material onto a substrate through the slits, wherein each of the slits has sidewalls inclined to a surface of the mask assembly at a first inclined angle;
a substrate holder configured to hold the substrate and located opposite the evaporation source with respect to the mask assembly; and
a process chamber configured to accommodate the evaporation source, substrate holder and mask assembly,
to wherein the evaporation source has a maximum spray angle less than the first inclined angle.

11. The deposition apparatus according to claim 10, wherein the maximum spray angle of the evaporation source is less than about 60°.

12. The deposition apparatus according to claim 10, wherein the evaporation source further comprises:
a crucible being open on one side thereof and configured to store the deposition material;
a nozzle section located on the open side of the crucible and having a plurality of nozzles, wherein each of the nozzles has a sidewall configured to spray the deposition material therethrough, and wherein the side wall has i) an inclined portion and ii) a non-inclined portion which is closer to the crucible than the inclined portion;
a heater configured to heat the crucible; and
a housing configured to accommodate the crucible, the nozzle section, and the heater.

13. The deposition apparatus according to claim 12, wherein the inclined portion has a height (h), which satisfies the following expression:
$$h = \frac{tan ( 90 - \frac{θ}{2} ) tan θ}{tan ( 90 - \frac{θ}{2} ) - tan θ} R$$
where θ is the maximum spray angle of the nozzle section, and R is the inner diameter of the non-inclined portion of the side wall.

14. The deposition apparatus according to claim 12, wherein the inclined portion has a top and a bottom which is closer to the crucible than the top, wherein the inclined portion is substantially gradually inclined such that the inner diameter of the top is greater than that of the bottom, wherein the is thickness (t) of the bottom of the inclined portion satisfies the following expression:
$$t = \frac{tan θ}{tan ( 90 - \frac{θ}{2} ) - tan θ} R$$
where θ is the maximum spray angle of the nozzle section, and R is the inner diameter of the non-inclined portion of the side wall, and wherein the thickness (t) is substantially the same as the thickness of the non-inclined portion of the side wall.

15. The deposition apparatus according to claim 12, wherein the inclined portion has a height (h) and thickness (t), which satisfy the following expression:
$$\frac{h}{t} = tan ( 90 - \frac{θ}{2} )$$
where θ is the maximum spray angle of the nozzle section, wherein the inclined portion has a top and a bottom which is closer to the crucible than the top, wherein the inclined portion is substantially gradually inclined such that the inner diameter of the top is greater than that of the bottom, and wherein t is the thickness of the bottom of the inclined portion which is substantially the same as the thickness of the non-inclined portion of the side wall.

16. The deposition apparatus according to claim 10, further comprising a transfer unit configured to reciprocate the evaporation source in a predetermined direction.

17. An evaporation source for manufacturing flat panel displays, comprising:
a container configured to store a deposition material;
a nozzle being in fluid communication with the container, wherein the nozzle has a sidewall configured to spray the deposition material onto a substrate to be deposited, wherein the side wall has an inclined portion, wherein the inclined portion has a top and a bottom which is closer to the container than the top, and wherein the top of the inclined portion forms an inclined angle with respect to the bottom such that the inner diameter of the top is greater than that of the bottom, and wherein the inclined angle is greater than about 60° and less than 90°; and
a housing configured to accommodate the container and the nozzle.

18. The evaporation source according to claim 17, wherein the nozzle has a maximum spray angle less than about 60°.

19. The evaporation source according to claim 17, wherein the side wall includes a non-inclined portion which is closer to the container than the inclined portion, wherein the thickness (t) of the bottom of the inclined portion satisfies the following expression:
$$t = \frac{tan θ}{tan ( 90 - \frac{θ}{2} ) - tan θ} R$$
where θ is the maximum spray angle of the nozzle section, and R is the inner diameter of the non-inclined portion of the side wall, and wherein the thickness (t) is substantially the same as the thickness of the non-inclined portion of the side wall of the nozzle.

20. The evaporation source according to claim 17, wherein the side wall includes a non-inclined portion which is closer to the container than the inclined portion, wherein the inclined portion has a height (h) and thickness (t), which satisfy the following expression:
$$\frac{h}{t} = tan ( 90 - \frac{θ}{2} )$$
where θ is the maximum spray angle of the nozzle section, and wherein t is the thickness of the bottom of the inclined portion which is substantially the same as the thickness of the non-inclined portion of the side wall.
